(19) United States
(12) Patent Application Publication
(10) Pub. No.: US 2022/0301958 A1
(43) Pub. Date: Sep. 22, 2022

(54) SEMICONDUCTOR PACKAGE

(71) Applicant: SAMSUNG ELECTRONICS CO., LTD., SUWON-SI (KR)

(72) Inventors: SUNGWOO PARK, SEONGNAM-SI (KR); SOOHYUN NAM, SEONGNAM-SI (KR); HYUNJUNG SONG, HWASEONG-SI (KR); MINSEUNG YOON, YONGIN-SI (KR)

(21) Appl. No.: 17/535,937

(22) Filed: Nov. 26, 2021

(30) Foreign Application Priority Data
Mar. 22, 2021 (KR) 10-2021-0036501

(51) Int. Cl. H01L 23/29; H01L 23/31; H01L 23/00; H01L 23/367; H01L 25/18

(52) U.S. Cl. CPC H01L 23/293; H01L 23/3121; H01L 23/3135; H01L 24/32; H01L 23/367; H01L 25/18; H01L 2224/32225

(57) ABSTRACT

A semiconductor package includes a circuit board mounting a first semiconductor chip and a second semiconductor chip laterally separated by an intermediate space, an underfill including an extended portion protruding upward into the intermediate space, a surface modification layer on opposing side surfaces of the first semiconductor chip and the second semiconductor chip, wherein wettability of the underfill with respect to the surface modification layer is less than wettability of the underfill with respect to the side surfaces of the first semiconductor chip and the second semiconductor chip, and a molding member on the upper surface of the circuit board, covering an upper surface of the extended portion of the underfill, and surrounding the first semiconductor chip and the second semiconductor chip.

### CROSS-REFERENCE TO RELATED APPLICATION

This U.S. nonprovisional application claims priority under 35 U.S.C. § 119 to Korean Patent Application No. 10-2021-0036501 filed on Mar. 22, 2021 in the Korean Intellectual Property Office, the subject matter of which is hereby incorporated by reference in its entirety.

### BACKGROUND

The inventive concept relates generally to semiconductor packages including a semiconductor chip.

With the development of the electronics industry, demand for high functionality, high speed, and miniaturized electronic components is increasing. In accordance with this trend, semiconductor packages may be manufactured by mounting semiconductor chips on a single interposer or a package substrate. However, warpage may occur in the semiconductor package due to differences in the coefficients of thermal expansion (CTE) for respective components constituting the semiconductor package. Improved approaches to addressing the issue of warpage in semiconductor packages are required.

### SUMMARY

Embodiments of the inventive concept provide semiconductor packages exhibiting improved immunity to warpage, and therefore improved reliability.

According to one embodiment of the inventive concept, a semiconductor package includes; a circuit board including first upper pads and second upper pads on an upper surface of the circuit board, a first semiconductor chip on the upper surface of the circuit board electrically connected to the first upper pads, and a second semiconductor chip on the upper surface of the circuit board electrically connected to the second upper pads, wherein opposing side surfaces of the first semiconductor chip and the second semiconductor chip are separated by an intermediate space, an underfill between a lower surface of the first semiconductor chip and a lower surface of the second semiconductor chip and the upper surface of the circuit board, wherein the underfill includes an extended portion protruding upward into the intermediate space, a surface modification layer on the opposing side surfaces of the first semiconductor chip and the second semiconductor chip, wherein wettability of the underfill with respect to the surface modification layer is less than wettability of the underfill with respect to the side surfaces of the first semiconductor chip and the second semiconductor chip, and a molding member on the upper surface of the circuit board, covering an upper surface of the extended portion of the underfill, and substantially surrounding the first semiconductor chip and the second semiconductor chip.

According to another embodiment of the inventive concept, a semiconductor package includes; a circuit board including an upper surface mounting a first semiconductor chip and mounting a second semiconductor chip adjacent to the first semiconductor chip, such that opposing side surfaces of the first semiconductor chip and second semiconductor chip are separated by an intermediate space, a surface modification layer on the opposing side surfaces of the first semiconductor chip and the second semiconductor chip, an underfill disposed between the first semiconductor chip and the second semiconductor chips and the circuit board, wherein the underfill includes an extended portion protruding into the intermediate space and having a height 40% or less of a mounting height of the first semiconductor chip, and a molding member substantially surrounding the first semiconductor chip and the second semiconductor chip, wherein an upper surface of the first semiconductor chip and an upper surface of the second semiconductor chip are coplanar with an upper surface of the molding member.

According to still another embodiment of the inventive concept, a semiconductor package includes; a circuit board including an upper surface mounting a semiconductor chip and mounting a dummy chip adjacent to the semiconductor chip, such that opposing side surfaces of the semiconductor chip and dummy chip are separated by an intermediate space, a surface modification layer on the opposing side surfaces of the semiconductor chip and the dummy chip, wherein, wettability of the underfill with respect the surface modification layer is less than wettability of the underfill with respect to the opposing side surfaces of the semiconductor chip and the dummy chip, an underfill disposed between the semiconductor chip and the circuit board and including an extended portion protruding into the intermediate space, and a molding member substantially surrounding the semiconductor chip and the dummy chip.

### BRIEF DESCRIPTION OF DRAWINGS

The making and use of the inventive concept may be more clearly understood upon consideration of the following detailed description together with the accompanying drawings, in which:

FIG. 1 is a plan view of a semiconductor package according to embodiments of the inventive concept;

FIG. 2 is a cross-sectional view taken along line I-I′ of FIG. 1;

FIG. 3 is an enlarged cross-sectional view of portion ‘A’ indicated in FIG. 2;

FIGS. 4A and 4B are comparative views illustrating change in the wettability of an underfill material as a function of contact angle;

FIGS. 5A, 5B, 5C and 5D are related cross-sectional views illustrating in one example a method of manufacturing a semiconductor chip that may be included in a semiconductor package according to embodiments of the inventive concept;

FIGS. 6A, 6B, 6C and 6D are related cross-sectional views illustrating in another example a method of manufacturing semiconductor packages according to embodiments of the inventive concept;

FIG. 7 is a plan view of a semiconductor package according to embodiments of the inventive concept, and FIG. 8 is a cross-sectional view taken along line I-I′ of FIG. 7;

FIG. 9 is a top view of a semiconductor package according to embodiments of the inventive concept;

FIGS. 10A and 10B are respective cross-sectional views taken along lines I1-I1′ and I2-I2′ of FIG. 9;

FIG. 11 is a cross-sectional view taken along line II-II′ of FIG. 9; and

FIG. 12 is a cross-sectional view of a semiconductor package according to embodiments of the inventive concept.

### DETAILED DESCRIPTION

Throughout the written description and drawings, like reference numbers and labels are used to denote like or similar elements and/or features. Throughout the written description certain geometric terms may be used to highlight relative relationships between elements, components and/or features with respect to certain embodiments of the inventive concept. Those skilled in the art will recognize that such geometric terms are relative in nature, arbitrary in descriptive relationship(s) and/or directed to aspect(s) of the illustrated embodiments. Geometric terms may include, for example: height/width; vertical/horizontal; top/bottom; higher/lower; closer/farther; thicker/thinner; proximate/distant; above/below; under/over; upper/lower; center/side; surrounding; overlay/underlay; etc.

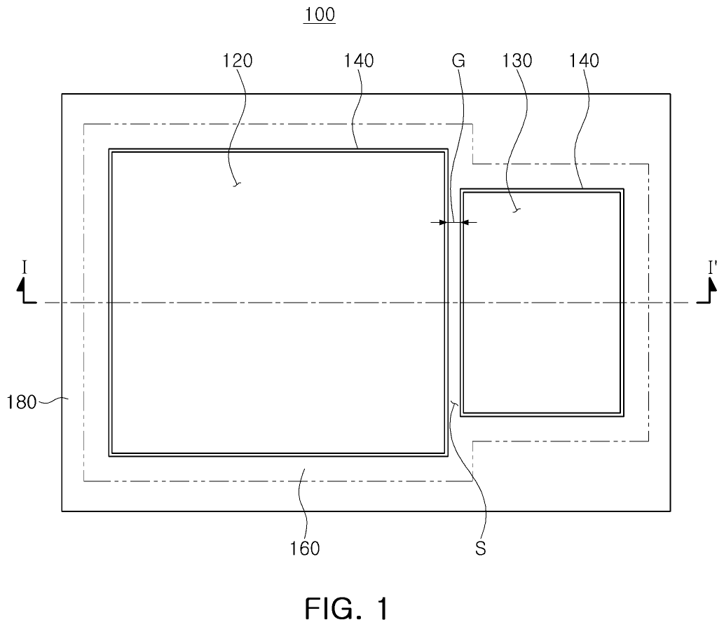

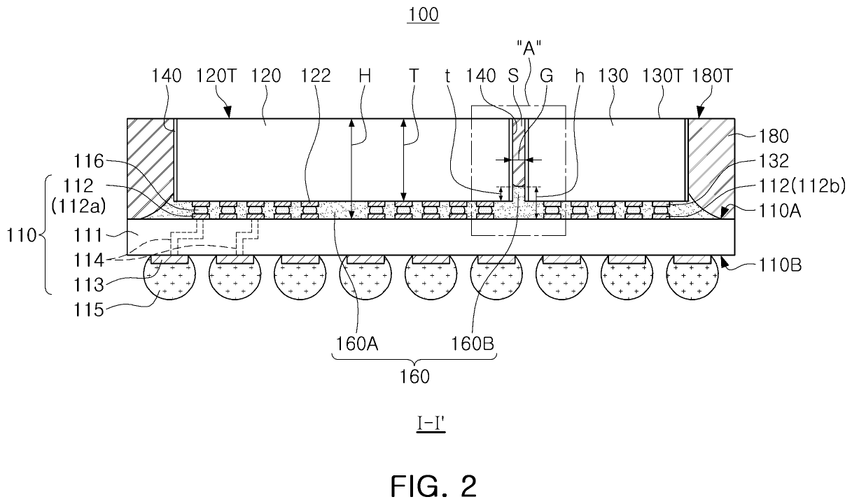

FIG. 1 is a plan (or top-down) view of a semiconductor package 100 according to embodiments of the inventive concept, and FIG. 2 is a cross-sectional view taken along line I-I′ of FIG. 1.

Referring to FIGS. 1 and 2, the semiconductor package 100 may include a circuit board 110 having an upper surface 110A and an opposing lower surface 110B, a first semiconductor chip 120 and a second semiconductor chip 130 disposed (or mounted) on the upper surface 110A of the circuit board 110, an underfill 160 disposed between the upper surface 110A of the circuit board 110 and the first and second semiconductor chips 120 and 130, and a molding member 180 covering the first and second semiconductor chips 120 and 130.

The circuit board 110 may include a wiring circuit 114 formed in a substrate 111, as well as upper pads 112 and lower pads 113, respectively disposed on the upper and lower surfaces 110A and 110B of the circuit board 110 and variously connected by the wiring circuit 114. In FIG. 1, only selected, illustrative portions of the wiring circuit 114 are indicated by dotted lines within the substrate 111. However, those skilled in the art will appreciate that the wiring circuit 114 portions associated with the upper and lower pads 112 and 113 may be variously disposed in relation to the semiconductor package 100.

In some embodiments, the first semiconductor chip 120 may include a logic chip (e.g., a Central Processing Unit (CPU), a controller, a microprocessor, etc.). In some embodiments, the second semiconductor chip 130 may include one or more memory chip(s) (e.g., a dynamic Random Access Memory (RAM) (DRAM), a static RAM (SRAM), flash memory, a phase-change RAM (PRAM), a resistive RAM (ReRAM), a ferroelectric RAM (FeRAM), and/or a magnetic RAM (MRAM). For example, the second semiconductor chip 130 may be a high-band memory (HBD) chip including a memory stack connected using a through-silicon-via (TSV) structure.

In some embodiments, the circuit board 110 may be an interposer 110, and the substrate 111 may be a silicon substrate. Alternately, the circuit board 110 may be a printed circuit board (PCB).

External terminals 115 may be selectively associated with the lower pads 113, and may be disposed on the lower surface 110B of the circuit board 110. In this regard, for example, the external terminals 115 may include one or more materials, such as tin (Sn), lead (Pb), nickel (Ni), gold (Au), silver (Ag), copper (Cu), bismuth (Bi), and/or alloys of same.

Each of the first and second semiconductor chips 120 and 130 may include an active surface facing the upper surface 110A of the circuit board 110, as well as an opposing, inactive surface (e.g., upper surface 120T and upper surface 130T). The first semiconductor chip 120 may include first connection electrodes 122 variously disposed on its active surface, and the second semiconductor chip 130 may include second connection electrodes 132 variously disposed on its active surface. One or more of the first connection electrodes 122 may be connected to one of first upper pads 112a via respective connection bumps 116, and one or more of the second connection electrodes 132 may be connected to one of second upper pads 112b via respective connection bumps 116. Here, the combination of the first upper pads 112a and the second upper pads 112b form a constellation of upper pads 112.

The underfill 160 may be disposed between the upper surface 110A of the circuit board 110 and the first and second semiconductor chips 120 and 130. That is, the underfill 160 may substantially fill space(s) between the connection bumps 160, thereby protecting the upper pads 112, the connection bumps 116, and active surfaces of the first and second semiconductor chips 120 and 130 from contamination and mechanical impact. In some embodiments, the underfill 160 may include at least one insulating polymer material, such as an epoxy resin.

The molding member 180 may be disposed on the upper surface 110A of the circuit board 110 to substantially surround the first and second semiconductor chips 120 and 130. Here, the molding member 180 may include an insulating polymer material. In some embodiments, one or more insulating polymer material(s) used in the underfill 160 may be the same or substantially similar to one or more insulating polymer material(s) used in the molding member 180. However, the underfill 160 should have a relatively high fluidity in order to effectively fill relatively small spaces. Thus, a modulus of the underfill 160 may be lower than a modulus of the molding member 180. In one example, therefore, the underfill 160 may include at least one insulating polymer material, identical or substantially similar to that of the molding member 180. However, one or more filler(s) may be variously used (e.g., in relation to type and an amount) to adjust the modulus of the underfill 160 and/or the modulus of the molding member 180. In some embodiments, a coefficient of thermal expansion for the underfill 160 may be higher than a coefficient of thermal expansion for the molding member 180.

As illustrated in FIG. 2, the underfill 160 may be understood as including a main portion 160A substantially overlaying the upper surface 110A of the circuit board 110 and an extended portion 160B protruding upward from the main portion 160A into at least a portion of an intermediate space S between laterally opposing sidewalls of the first and second semiconductor chips 120 and 130. In this regard, the extended portion 160B of the underfill 160 may arise as a result of efforts to protect the components of first and second semiconductor chips 120 and 130. However, presence and geometry of the extended portion 160B of the underfill 160 may play an important role in efforts to suppress or prevent warpage of the semiconductor package 100.

Of note in this regard, the intermediate space S may act, at least in comparative semiconductor packages, as an inflection point for warpage of the semiconductor package. In particular, assuming that the underfill 160 has a relatively low modulus, serious warpage may occur in relation to the upward extension of the extending portion 160B of the underfill 160 into the intermediate space S.

Further in this regard, the potential for warpage of the semiconductor package 100 may be reduced as a spacing gap G defining the lateral “width” of the intermediate space S is decreased. Unfortunately, a reduction in the width of the spacing gap G may actually increase the capillary force drawings the extended portion 160B of the underfill 160 upward into the intermediate space S. Therefore, in order to reduce the possibility of warpage in the semiconductor package 100, an approach in required that suppresses the upward draw (and therefore the vertical extension) of the extended portion 160B of the underfill 160, while also allowing for a reduction in the lateral width of the gap G.

Accordingly, if the vertical “height” of the extended portion 160B of the underfill 160 upwardly into the intermediate space S is reduced, the a residual portion of the intermediate space S may be filled with the molding member 180 having a greater rigidity than the underfill 160. In this manner, the possibility of warpage in the semiconductor package 100 associated with the intermediate space S between the first and second semiconductor chips 120 and 130 may be reduced or eliminated.

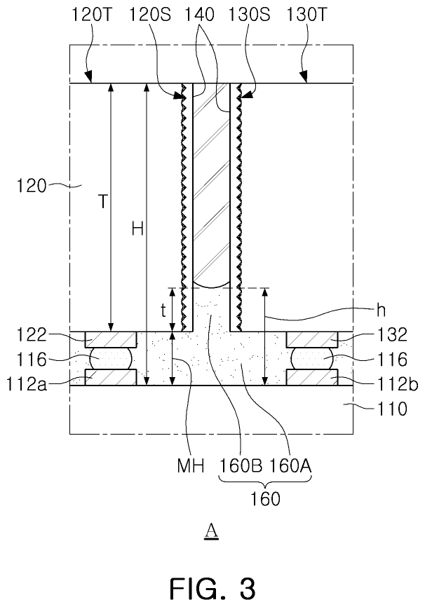

Referring to FIGS. 2 and 3, the first and second semiconductor chips 120 and 130 may include a surface modification layer 140 respectively applied to laterally opposing side surfaces 120S and 130S of the first and second semiconductor chips 120 and 130. Here, the surface modification layer 140 may serve to reduce wettability of the underfill 160 on the side surfaces 120S and 130S of the first and second semiconductor chips 120 and 130. That is, wettability of the underfill 160 with respect to material(s) included in the surface modification layer 140 may be markedly less than wettability of the underfill 160 with respect to materials (e.g., silicon) included in the side surfaces 120S and 130S of the first and second semiconductor chips 120 and 130.

As noted above, the intermediate space S between the first and second semiconductor chips 120 and 130 tends to draw up the extended portion 160B of the underfill 160 before curing of the semiconductor package 100 due in large part to surface tension between the opposing lateral side walls 120S and 130S. Hence, the surface modification layer 140 may be employed to effectively reduce surface tension (e.g., reduce an innate attraction between proximate molecules) by reducing wettability of the underfill 160 with respect to the side surfaces 120S and 130S of the first and second semiconductor chips 120 and 130. Due to this reduced surface tension, a height ‘h’ (e.g., measured from the upper surface 110A of the circuit board 110) of the extended portion 160B of the underfill 160 may be reduced, thereby suppressing potential warpage.

In some embodiments, the height h of the extended portion 160B of the underfill 160 may be 40% or less of a top surface mounting height ‘H’ for the first semiconductor chip 120 and/or the second semiconductor chip 130 (as measured from the upper surface 110A of the circuit board 110).

Further in this regard, a “corner height” ‘t’ of the first semiconductor chip 120 covered by the extended portion 160B of the underfill 160 may be 35% or less of a “thickness” T of the first semiconductor chip 120. For example, the corner height t of the first semiconductor chip 120 may be 250 μm or less. In this regard, the thickness T of the first semiconductor chip 120 and/or and second semiconductor chip 130 may be understood as excluding a stacked height MH (e.g., 30 μm to 50 μm) associated with a bonding structure from the overall mounting height H. In some embodiments, the corner height t of the first semiconductor chip 120 may range from about 2% to about 30% of the thickness T of the first semiconductor chip 120 (e.g., the corner height t may range from about 10 μm to about 200 μm).

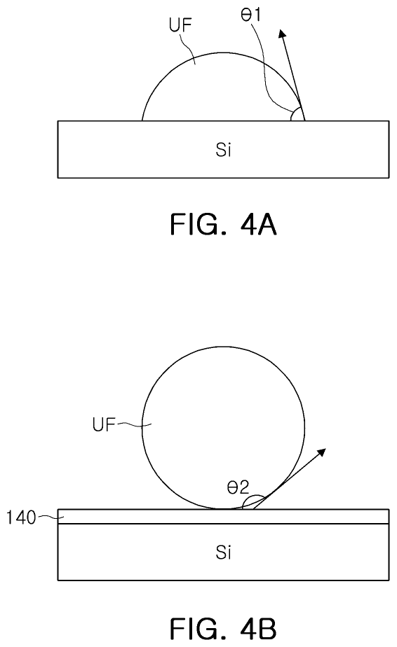

FIGS. 4A and 4B are conceptual diagrams illustrating a change in wettability of an underfill (UF) material as a function of contact angle. In this regard, the underfill material may behave like water.

Referring to FIG. 4A, an underfill UF may have a first contact angle θ1 on a surface of a semiconductor chip (e.g., silicon Si). Referring to FIG. 4B, an underfill UF on a surface of a surface modification layer 140 may have a second contact angle θ2, greater than the first contact angle θ1. A magnitude of an actual contact angle may vary depending on an applied underfill material, but elevation of an underfill 160 in a space S between first and second semiconductor chips 120 and 130 may be effectively reduced by increasing the contact angle (e.g., lowering wettability) due to the introduction of the surface modification layer 140.

In order to maximize the reduction in elevation of the underfill 160 in some embodiments, the surface modification layer 140 may be formed of a material providing a superhydrophobic surface. Thus superhydrophobic surface may be expressed in terms of a water contact angle, and may be defined as providing wettability having a water contact angle of 150° or more.

In some embodiments, the surface modification layer 140 may include a polymer coating layer. That is, the surface modification layer 140 may include at least one of polyimide, benzocyclobutene, fluoroalkylsilane, polytetrafluoroethylene (PTFE), an alkyl ketene dimer, and polyalkylpyrrole, etc. With respect to a water contact angle, a contact angle provided by fluoroalkylsilane or polytetrafluoroethylene (PTFE) may be about 165°, and contact angles provided by alkyl ketene dimer and polyalkylpyrrole may be about 174° and about 154°, respectively. Therefore, the surface modification layer 140 may significantly reduce wettability of the underfill 160. However, the surface modification layer 140 is not limited to only polymer coating layer(s), and alternately or additionally, material(s) such as carbon nanotubes (a water contact angle of about 165°) and modified silica (a water contact area of about 165°) may be used.

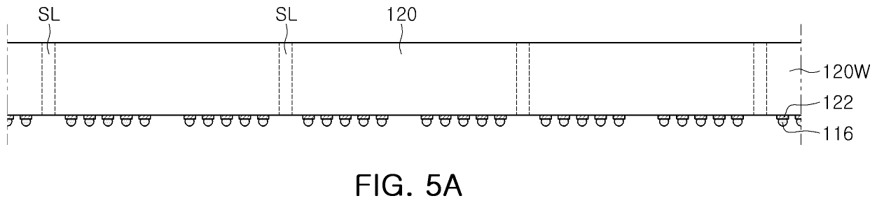

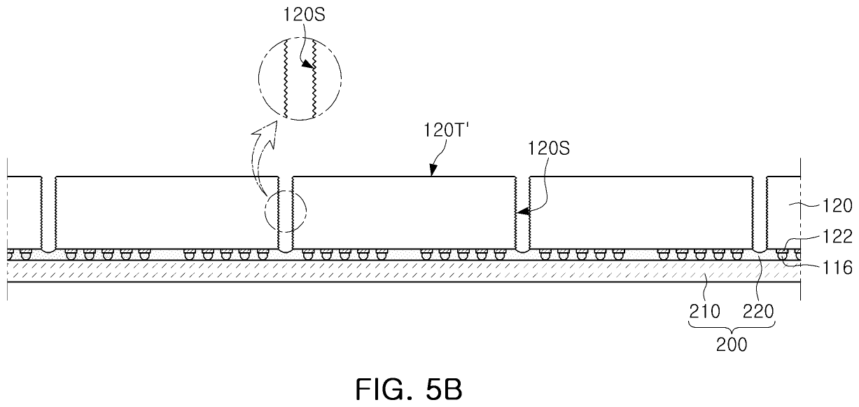

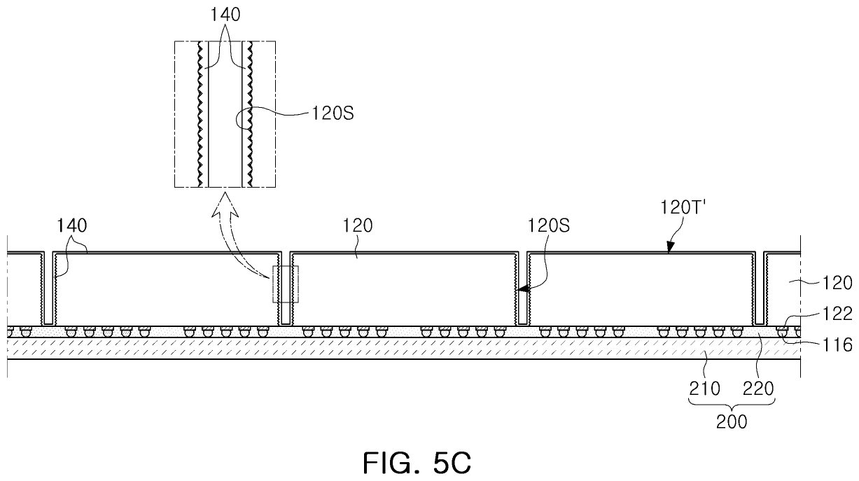

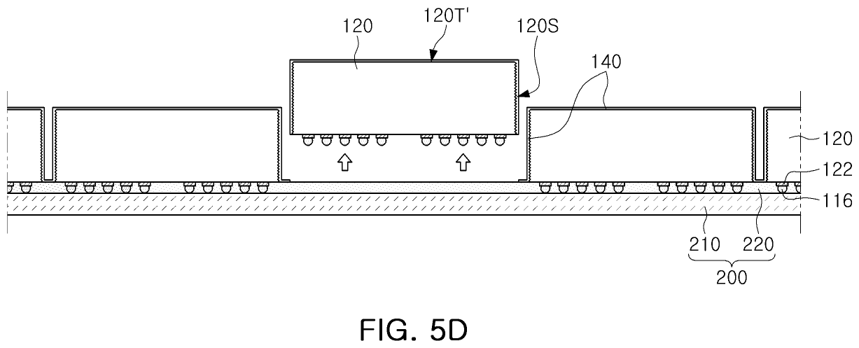

In some embodiments, the surface modification layer 140 may have a width of about 0.1 μm to about 5 μm. The surface of the surface modification layer 140 may have surface roughness, less than surface roughness of the side surfaces 120S and 130S of the first and second semiconductor chips 120 and 130. For example, the side surfaces 120S and 130S of the first and second semiconductor chips 120 and 130 may have relatively rough side surfaces due to a cutting process (e.g., a Bosch plasma etching) (see FIG. 5B), and these relatively rough side surfaces may be smoothed by the addition of the surface modification layer 140. (See, e.g., FIG. 5C). And due to the reduction in side surface roughness, the contact area between the underfill 160 and the side surfaces may be reduced, thereby further reducing the height of the extended portion 160B of the underfill 160.

In the illustrated example of FIG. 2, the first and second semiconductor chips 120 and 130 have substantially the same mounting height H. That is, the first and second semiconductor chips 120 and 130 may have respective upper surfaces 120T and 130T that are substantially coplanar with an upper surface 180T of the molding member 180.

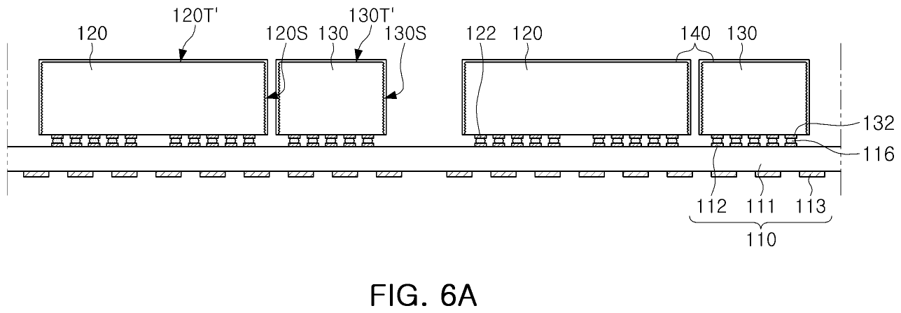

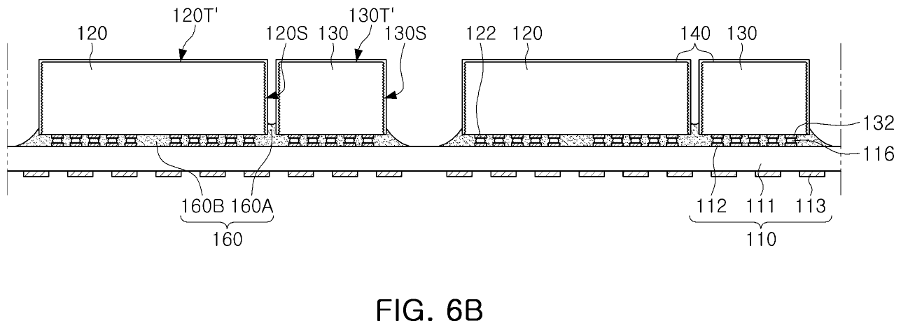

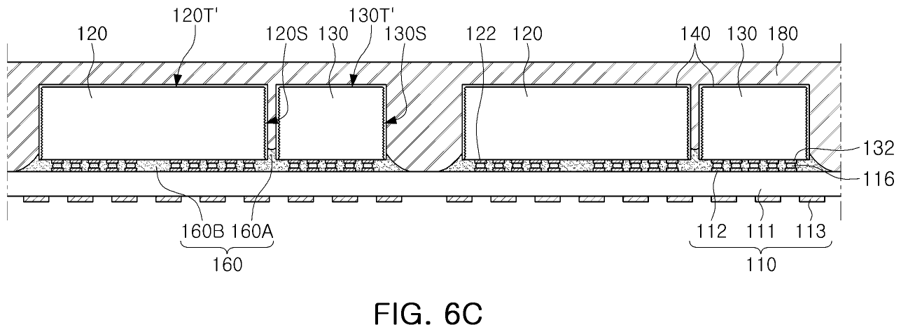

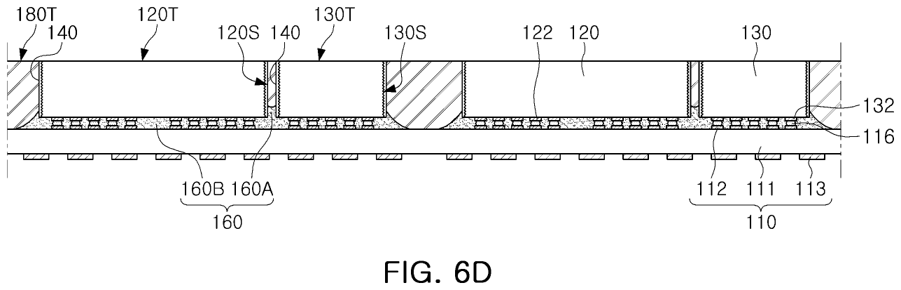

In this regard, the surface modification layer 140 may be applied to side surfaces 120S and 130S of the first and second semiconductor chips 120 and 130, but may not be applied on the upper surfaces 120T and 130T of the first and second semiconductor chips 120 and 130. Accordingly, the planar upper surfaces 120T and 130T of the first and second semiconductor chips 120 and 130 may be exposed using a conventional planarization process, such as a chemical mechanical polishing (CMP) process, an etch-back process or a combination thereof. After planarization, residual portion(s) of the surface modification layer 140 exposed on the upper surfaces 120T and 130T of the first and second semiconductor chips 120 and 130 may be removed, substantially leaving the surface modification layer 140 on only on the side surfaces 120S and 130S of the first and second semiconductor chips 120 and 130. (See, e.g., FIG. 6D).

FIGS. 5A, 5B, 5C and 5D are related cross-sectional views illustrating in one example a method of manufacturing semiconductor chip(s) that may be included in semiconductor packages according to embodiments of the inventive concept. FIGS. 6A, 6B, 6C and 6D are cross-sectional views illustrating in one example a method of manufacturing semiconductor packages according to embodiments of the inventive concept.

Referring to FIG. 5A, a semiconductor wafer 120W including first semiconductor chips 120 may be prepared. Here, the respective first semiconductor chips 120 may be divided on the semiconductor wafer 120W along a scribe lane SL. A lower surface of the semiconductor wafer 120W may be an active surface on which a device layer is formed. Connection pads 122 may be disposed on the lower surface of the semiconductor wafer 120W, and connection bumps 116 may be disposed on the connection pads 122, respectively. A conductive material constituting the connection bumps 116 may include a pillar structure and a solder layer, sequentially formed by an electroplating process. Subsequently, connection bumps 116 having a convex shape may be formed by performing a reflow process.

Next, referring to FIG. 5B, the semiconductor wafer 120W having the connection bumps 116 formed thereon may be attached to a carrier substrate 200, and a cutting process may be performed along the scribe line SL to singulate the first semiconductor chips 120.

The carrier substrate 200 may include a support substrate 210 and an adhesive material layer 220 disposed on the support substrate 210. The semiconductor wafer 120W may be attached to the adhesive material layer 220 such that the connection bumps 116 faces the carrier substrate 200. The connection bumps 116 may be surrounded by the adhesive material layer 220, and may be protected during subsequent processing. A portion of the lower surface of the semiconductor substrate 120W in which the connection bumps 116 are not formed may contact the adhesive material layer 220.

As noted above, the side surfaces 120S of the singulated first semiconductor chip 120 may have a relatively rough surface. For example, when a Bosch plasma etching method is performed, a periodic uneven shape may be formed and the side surfaces 120S may have high degree of surface roughness.

Next, referring to FIG. 5C, a surface modification layer 140 may be formed on exposed surfaces of the first semiconductor chips 120.

In some embodiments, the surface modification layer 140 may be conformally formed on side surfaces 120S and upper surface 120T of each first semiconductor chip 120. The surface modification layer 140 may include a material reducing wettability of an underfill on surfaces of a semiconductor. Such a surface modification layer is not limited thereto, but may be formed of a material having superhydrophobic properties, and in certain embodiments, a polymer coating layer may be used. In some embodiments, a material film of the surface modification layer 140 may be conformally deposited in a plasma atmosphere by generating plasma in a reactive gas. For example, the process of forming the surface modification layer 140 may be performed using a plasma deposition facility having a remote plasma CVD method, a microwave plasma CVD method, or an inductively coupled plasma (ICP) method.

The surface modification layer 140 may alleviate some of the roughness of the side surfaces of the first semiconductor chip 120. Due to reduction in the surface roughness of the side surfaces, a contact area between the underfill 160 and the side surfaces may be reduced. Therefore, the height of the extended portion 160B of the underfill 160 caused by surface tension may be reduced.

Next, referring to FIG. 5D, the first semiconductor chips 120 may be individually picked up, and as illustrated in FIG. 6A, each of the first semiconductor chips 120 may be transferred to and mounted on the circuit board 110 to be connected to the upper pads 112. The second semiconductor chip 130 including a surface modification layer 140 may be similarly provided, as described in FIGS. 5A to 5D. Thereafter, the second semiconductor chip 130 may be mounted on the circuit board 110 to be connected to the upper pads 112 adjacent to the first semiconductor chip 120.

Next, referring to FIG. 6B, the underfill 160 may be formed to substantially fill space(s) between lower surfaces of the first and second semiconductor chips 120 and 130 and an upper surface 110A of the circuit board 110.

In this regard, the extended portion 160B of the underfill 160 may be formed in the intermediate space S between the first and second semiconductor chips 120 and 130 (e.g., connecting the side surfaces 120S and 130S of the first and second semiconductor chips 120 and 130) due to surface tension. However, the surface modification layer 140 reduces the wettability of the underfill 160 in relation to the side surfaces 120S and 130S of the first and second semiconductor chips 120 and 130. Accordingly, the height h of the extended portion 160B may be notably reduced, thereby reducing or eliminating the possibility of warpage in the semiconductor package 100.

Subsequently, referring to FIG. 6C, the molding member 180 may be formed to cover the first and second semiconductor chips 120 and 130. During this process, the molding member 180 may be formed on side surfaces and upper surfaces of the first and second semiconductor chips 120 and 130.

Next, referring to FIG. 6D, a planarization process may be performed to expose the upper surfaces 120T and 130T of the first and second semiconductor chips 120 and 130.

Using the planarization process, a mounting height of the first semiconductor chip 120 may be substantially equal to a mounting height of the second semiconductor chip 130. Further, the upper surfaces 120T and 130T of the first and second semiconductor chips 120 and 130 may be substantially coplanar with an upper surface 180T of the molding member 180.

Following the planarization process, the surface modification layer 140 will remain only on the side surfaces 120S and 130S of the first and second semiconductor chips 120 and 130. That is, any residual portion of the surface modification layer 140 may be removed from the upper surfaces 120T and 130T of the first and second semiconductor chips 120 and 130 by the planarization process. In this regard, the planarization process may include a CMP process and/or an etch back process. Subsequently, a cutting process has been applied to separate the semiconductor packages, each including the first and second semiconductor chips 120 and 130 to provide the semiconductor package 100 of FIG. 1.

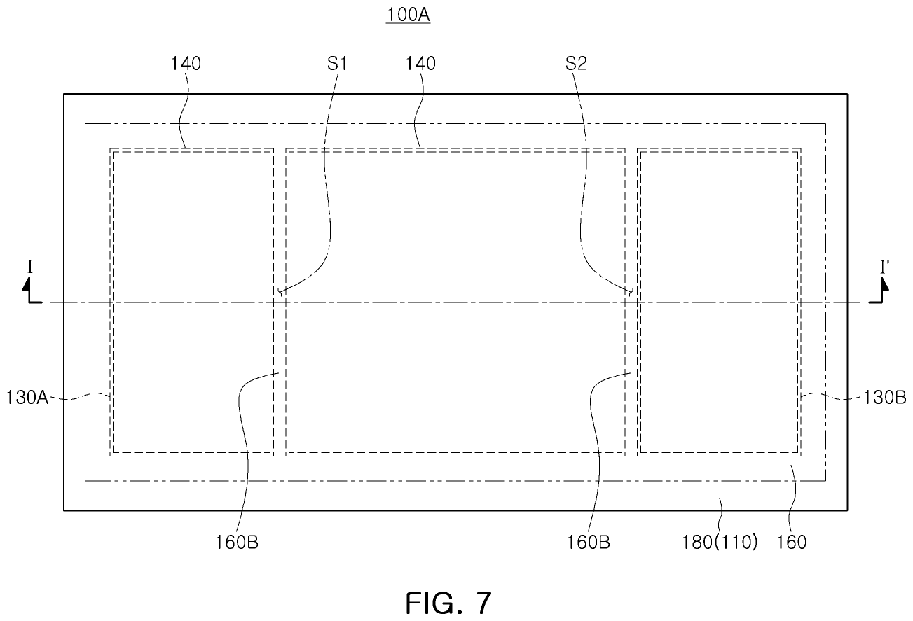

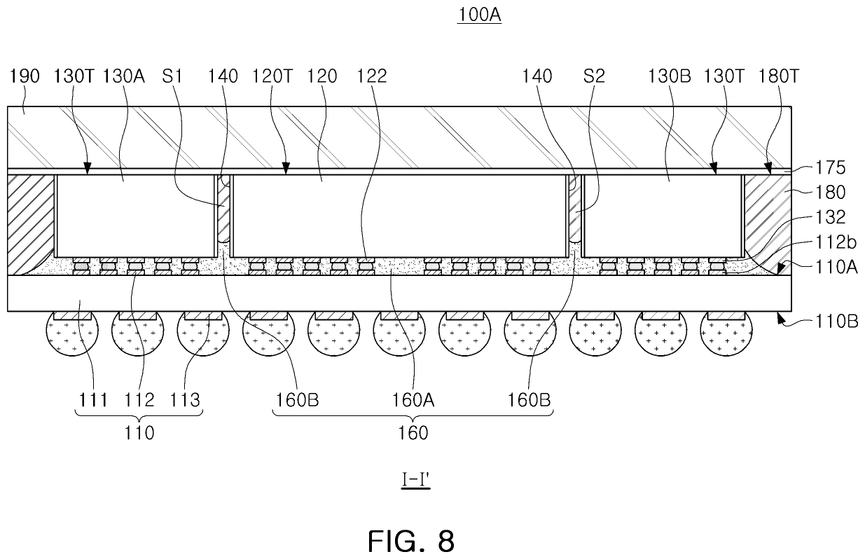

FIG. 7 is a plan view of a semiconductor package 100A according to embodiments of the inventive concept, and FIG. 8 is a cross-sectional view taken along line I-I′ of FIG. 7.

Referring to FIGS. 7 and 8, the semiconductor package 100A may be substantially similar to the semiconductor package 100 of FIGS. 1, 2 and 3, except two (2) second semiconductor chips 130A and 130B may be respectively disposed on opposing sides of the first semiconductor chip 120, and a heat sink may be (optionally) included. Hereafter, only material differences between the semiconductor package 100 of FIGS. 1, 2 and 3 and the semiconductor device 100A of FIGS. 7 and 8 will be described.

In some embodiments, the second semiconductor chips 130A and 130B may be respectively disposed on opposing sides of the first semiconductor chip 120 on the circuit board 110. The underfill 160 may this include the main portion 160A as well as first and second extending portions 160B respectively arising (or protruding upward) into first and second intermediate spaces S1 and S2 between the first semiconductor chip 120 and the second semiconductor chips 130A and 130B

However, as before, the vertical height of the extended portions 160B of the underfill 160 may be kept relatively low within the intermediate spaces S1 and S2 due to the application of the surface modification layer 140 to side surfaces 120S and 130S of the first and second semiconductor chips 120, 130A, and 130B.

Further, portions of the molding member 180 may cover the extended portions 160B of the underfill 160.

In the illustrated embodiment of FIGS. 7 and 8, the constituent nature, the process of application and the functional results of the surface modification layer 140 may be substantially similar to those previously described.

That is, by applying the surface modification layer 140 lowering wettability of the underfill 160, the height of the extended portions 160B of the underfill 160 elevating between adjacent side surfaces of the first semiconductor chip 120 and the second semiconductor chips 130A and 130B may be reduced. Accordingly, the risk of warpage in the semiconductor package 100A may be reduced.

Optionally, the semiconductor package 100A may further include a heat sink 190 disposed on an upper surface of the semiconductor package 100A. That is, the heat sink 190 may be attached to the upper surface of the semiconductor package 100A using a bonding member 175. Upper surfaces 120T and 130T of the first and second semiconductor chips 120, 130A, and 130B may be exposed from the upper surface of the semiconductor package 100A, and the upper surfaces 120T and 130T of the first and second semiconductor chips 120, 130A, and 130B may be substantially coplanar with an upper surface 180T of the molding member 180. The heat sink 190 may effectively dissipate heat generated from the first and second semiconductor chips 120, 130A, and 130B.

In some embodiments, the heat sink 190 may include a material having excellent thermal conductivity, such as metal and/or ceramic. In one example, the heat sink 190 may be a structure including a thermal interface material (TIM). For example, as the bonding member 175, NCF, ACF, a UV-sensitive film, an instant adhesive, a thermosetting adhesive, a laser curable adhesive, a ultrasonic curable adhesive, NCP, or the like may be used.

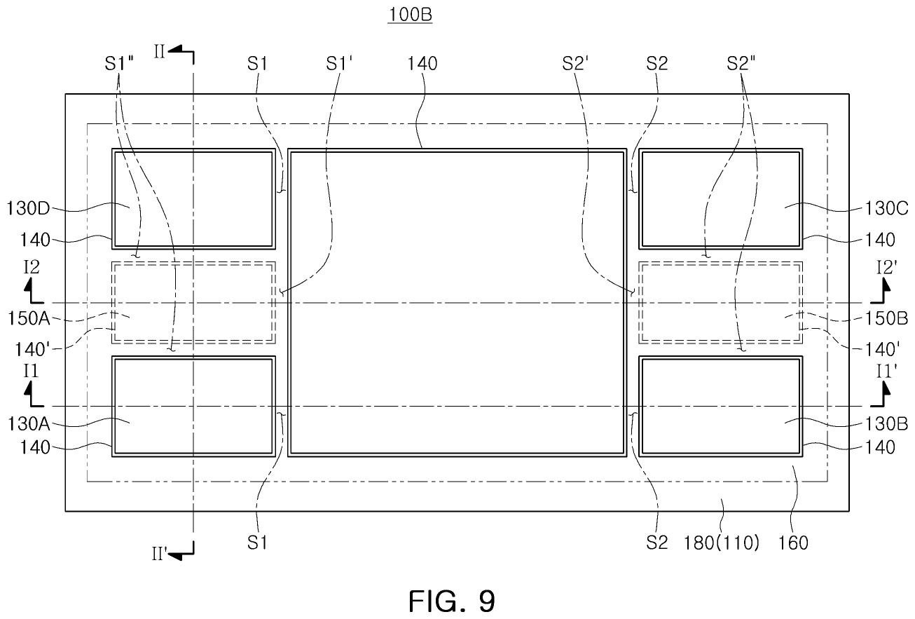

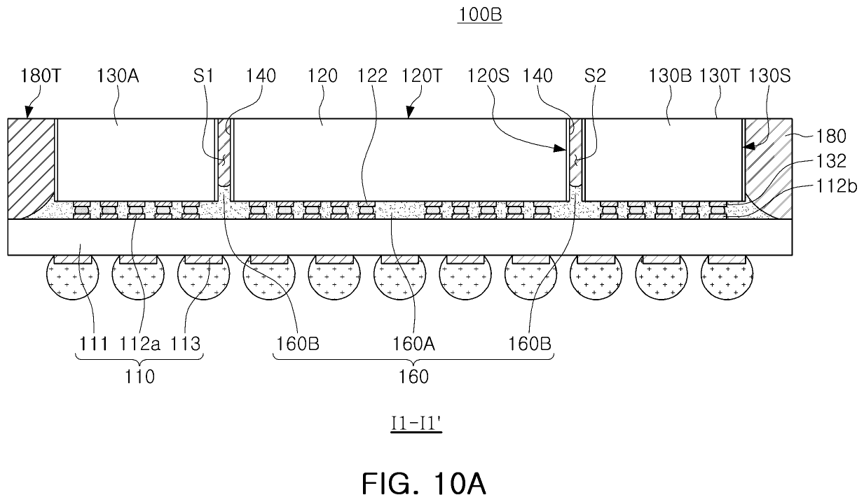

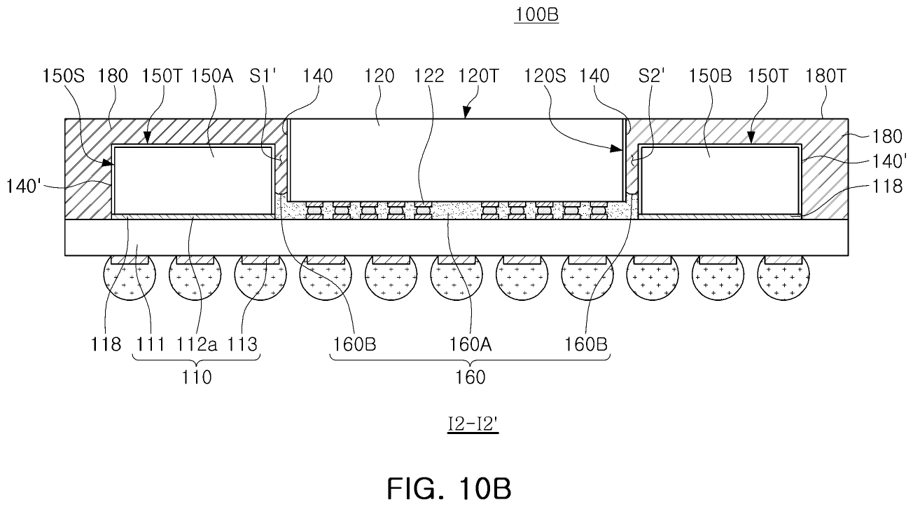

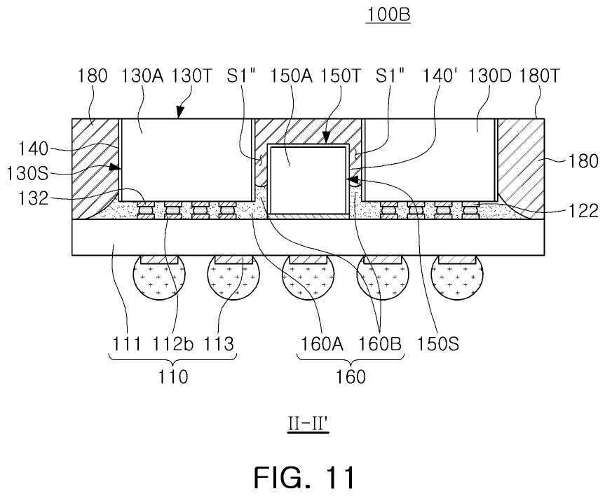

FIG. 9 is a top view of a semiconductor package 100B according to embodiments of the inventive concept, FIGS. 10A and 10B are respective cross-sectional views taken along lines I1-I1′ and I2-I2′ of FIG. 9, and FIG. 11 is a cross-sectional view taken along line II-II′ of FIG. 9.

Referring to FIGS. 9, 10A, 10B, and 11, the semiconductor package 100B may be substantially similar to the semiconductor package 100 of FIGS. 1, 2 and 3, except that two dummy chips 150A and 150B, together with the first semiconductor chip 120 and second semiconductor chips 130A, 130B, 130C, and 130D are used. Hereafter, only material differences between semiconductor package 100 of FIGS. 1, 2 and 3 and semiconductor package 100B of GIGS. 9, 10A, 10B and 11 will be described.

Here, the semiconductor package 100B may include the first semiconductor chip 120 and four (4) second semiconductor chips 130A, 130B, 130C, and 130D disposed around the first semiconductor chip 120. As illustrated in FIG. 9, pairs of the four (4) second semiconductor chips 130A, 130B, 130C, and 130D may be disposed on opposing side surfaces of the first semiconductor chip 120. Respective second connection electrodes 132 for each of the second semiconductor chips 130A, 130B, 130C, and 130D may be connected to upper pads 112 on the circuit board 110 using connection bumps 116.

In some embodiments, two (2) dummy chips 150A and 150B may be disposed between paired second semiconductor chips 130A and 130D and between paired second semiconductor chips 130B and 130C on opposing sides of the first semiconductor chip 120. The dummy chips 150A and 150B may be bonded to each other by the circuit board 110 using a bonding layer 118. As illustrated in FIG. 9, a side surface of each of the dummy chips 150A and 150B may face a side surface of the first semiconductor chip 120 together with side surfaces of the two second semiconductor chips 130A and 130D, and side surfaces of the two second semiconductor chips 130B and 130C, respectively. First intermediate spaces S1 and S2 between opposite side surfaces of the first semiconductor chip 120 and opposite side surfaces of the second semiconductor chips 130A and 130D, and between opposite side surfaces of the first semiconductor chip 120 and opposite side surfaces of the second semiconductor chips 130B and 130C, respectively, and second intermediate spaces S1′ and S2′ between opposite side surfaces of the first semiconductor chip 120 and opposite side surfaces of the dummy chips 150A and 150B, respectively, may be provided, wherein the first and second intermediate spaces S1, S2, S1′, and S2′ may be variously interconnected.

In addition, each of the dummy chips 150A and 150B may have side surfaces facing side surfaces of the two second semiconductor chips 130A and 130D and side surfaces of the two second semiconductor chips 130B and 130C, respectively. Third intermediate spaces S1″ and S2″ between the dummy chip 150A and opposite side surfaces of the two second semiconductor chips 130A and 130D and between the dummy chip 150B and opposite side surfaces of the two second semiconductor chips 130B and 130C, respectively, may be provided, and the third intermediate spaces S1″ and S2″ may be variously interconnected to the first intermediate spaces S1 and S2 and the second intermediate spaces S1′ and S2′ on both sides of the first semiconductor chip 120. Of further note, the first, second and third intermediate spaces S1, S2, S1′, S2′, S1″, and S2″ may have different widths.

Referring to FIG. 10A, the underfill 160 may include the main portion 160A substantially filling spaces between the first semiconductor chip 120 and the second semiconductor chips 130A, 130B, 130C, and 130D, and a first surface 110A of the circuit board 110, respectively, and extended portions 160B protruding upward between facing side surfaces of the first semiconductor chip 120 and the second semiconductor chips 130A, 130B, 130C, and 130D. Similarly, referring to FIG. 10B, the extended portion 160B of the underfill 160 may also protrude upward into the second intermediate spaces S1′ and S2′ along the facing surfaces of the first semiconductor chip 120 and the dummy chips 150A and 150B, even when the extended portion 160B includes relatively little material.

Referring to FIG. 11, the extended portion 160B of the underfill 160 may also protrude upward into the third intermediate spaces S1″ and S2″ along the facing side surfaces the second semiconductor chips 130 and the dummy chips 150A and 150B. With regard to the extended portion 160B, its height in each of the first intermediate spaces S1 and S2 may be greater than its height in each of the second intermediate spaces S1′ and S2′, and greater than its height in each of the third intermediate spaces S1″ and S2″.

Here, surface modification layers 140 and 140′ may be applied to the side surfaces of the first semiconductor chip 120, side surfaces of the second semiconductor chips 130A, 130B, 130C, and 130D, and the side surfaces of the two dummy chips 150A and 150B, respectively, may have relatively low wettability with respect to the underfill 160. Thus, the height of the extended portions 160B of the underfill 160 may be kept relatively low. In some embodiments, the height of the extended portion 160B may be 40% or less of a mounting height of the first semiconductor chip 120 (or each of the second semiconductor chips 130A, 130B, 130C, and 130D). In some embodiments, a corner height covered by the extended portion 160B of the underfill 160 may be 35% or less of a thickness of the first semiconductor chip 120.

The dummy chips 150A and 150B may include a surface modification layer 140′, similarly to the surface modification layer 140 of the first and second semiconductor chips. The surface modification layer 140′ may be applied by a process similar to that described in relation to FIGS. SA, 5B, 5C and 5D.

As illustrated in FIG. 10B, the dummy chips 150A and 150B may have a mounting height (or a thickness), greater than a mounting height (or a thickness) of the first semiconductor chip 120. With this particular configuration, although a planarization process is performed (FIG. 6C), upper surfaces 150T of the dummy chips 150A and 150B may remain covered with a molding member 180. As a result, as illustrated in FIGS. 10B and 11, the surface modification layer 140′ may exist on the upper surfaces 150T as well as the side surfaces 150S of the dummy chips 150A and 150B.

Consistent with the previously described embodiment, by introducing the surface modification layers 140 and 140′ lowering wettability of the underfill 160, the height of extended portions 160B of the underfill 160 arising between adjacent side surfaces of the first semiconductor chip 120 and the second semiconductor chips 130A, 130B, 130C, and 130D may be reduced. Therefore, the risk of warpage in the semiconductor packages may be greatly reduced or eliminated.

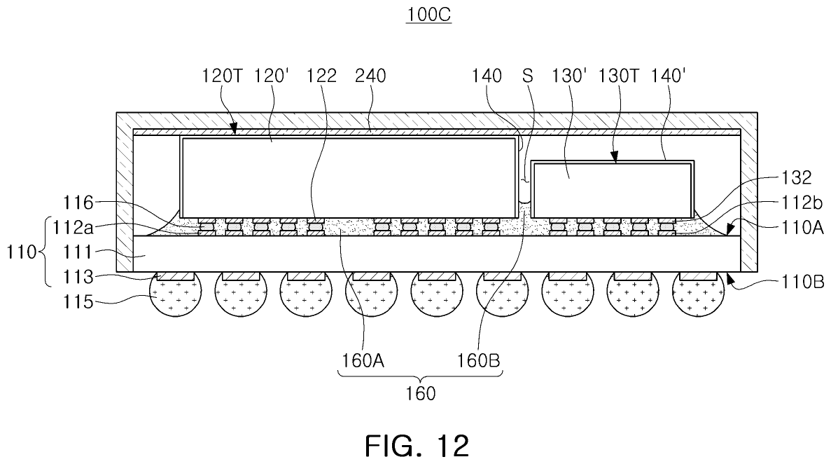

FIG. 12 is a cross-sectional view of a semiconductor package 100C according to embodiments of the inventive concept.

Referring to FIG. 12, the semiconductor package 100C may be substantially similar to the semiconductor package 100 of FIGS. 1, 2 and 3, except that first and second semiconductor chips 120′ and 130′ have different heights, and a protective cap 250 is included.

Here, the second semiconductor chip 130′ may have a mounting height (or a thickness), less than a mounting height (or a thickness) of the first semiconductor chip 120′. Similarly to the dummy chips 150A and 150B illustrated in FIGS. 10B and 11, the first and second semiconductor chips 120′ and 130′ may have a surface modification layer 140′ located on upper surfaces 120T and 130T, as well as side surfaces 120S and 130S. The surface modification layer 140′ may be formed by a process similar to the process of FIGS. 5A, 5B, 5C and 5D. Since a molding member formation (see FIG. 6B) and a planarization process (see FIG. 6C) are not used, the surface modification layer 140′ may also be present on the upper surfaces 120T and 130T.

The semiconductor package 100C may further include a protective cap 250 that protects the first and second semiconductor chips 120′ and 130′ mounted on a circuit board 110. The protective cap 250 may be bonded to the upper surface 120T of the first semiconductor chip 120 using a bonding member 240. For example, as the bonding member 240, NCF, ACF, a UV-sensitive film, an instant adhesive, a thermosetting adhesive, a laser curable adhesive, a ultrasonic curable adhesive, NCP, or the like may be used. The protective cap 250 may include a material having excellent thermal conductivity, such as a metal, and may effectively dissipate heat generated from the first semiconductor chip 120.

According to the above-described embodiment, the height of upwardly extending portion(s) of underfill between semiconductor chips, and/or between a semiconductor chip and a dummy chip may be suppressed by applying a surface modification layer capable of lowering wettability of the underfill to a surface of the semiconductor chip and a surface of dummy chip to at least side surfaces of the chips. Accordingly, the possibility of warpage in the semiconductor package due may be greatly reduced.

Various advantages and effects of the inventive concept are not limited to the above-described contents, and can be more easily understood in the process of describing specific embodiments of the inventive concept.

While example embodiments have been illustrated and described above, it will be apparent to those skilled in the art that modifications and variations could be made without departing from the scope of the inventive concept as defined by the appended claims.

What is claimed is:

1. A semiconductor package comprising:
a circuit board including first upper pads and second upper pads on an upper surface of the circuit board;
a first semiconductor chip on the upper surface of the circuit board electrically connected to the first upper pads, and a second semiconductor chip on the upper surface of the circuit board electrically connected to the second upper pads, wherein opposing side surfaces of the first semiconductor chip and the second semiconductor chip are separated by an intermediate space;
an underfill between a lower surface of the first semiconductor chip and a lower surface of the second semiconductor chip and the upper surface of the circuit board, wherein the underfill includes an extended portion protruding upward into the intermediate space;
a surface modification layer on the opposing side surfaces of the first semiconductor chip and the second semiconductor chip, wherein wettability of the underfill with respect to the surface modification layer is less than wettability of the underfill with respect to the side surfaces of the first semiconductor chip and the second semiconductor chip; and
a molding member on the upper surface of the circuit board, covering an upper surface of the extended portion of the underfill, and surrounding the first semiconductor chip and the second semiconductor chip.

2. The semiconductor package of claim 1, wherein the surface modification layer comprises a polymer coating layer.

3. The semiconductor package of claim 2, wherein the surface modification layer comprises at least one of polyimide, benzocyclobutene, fluoroalkylsilane, polytetrafluoroethylene (PTFE), an alkyl ketene dimer, and polyalkylpyrrole.

4. The semiconductor package of claim 2, wherein the surface modification layer has a thickness ranging between about 0.1 μm to about 5 μm.

5. The semiconductor package of claim 1, wherein a height of the extended portion of the underfill is 40% or less of a mounting height of the first semiconductor chip.

6. The semiconductor package of claim 1, wherein a corner height the first semiconductor chip covered by the extended portion of the underfill is 35% or less of a thickness of the first semiconductor chip.

7. The semiconductor package of claim 1, wherein a mounting height of the first semiconductor chip may be equal to a mounting height of the second semiconductor chip.

8. The semiconductor package of claim 7, wherein an upper surface of the first semiconductor chip and an upper surface of the second semiconductor chip are coplanar with an upper surface of the molding member.

9. The semiconductor package of claim 8, wherein the surface modification layer is only on the side surfaces of the first semiconductor chip and the second semiconductor chip.

10. The semiconductor package of claim 1, wherein a height of the extended portion of the underfill covering a lower portion of the side surface of the first semiconductor chip is 250 μm or less.

11. The semiconductor package of claim 10, wherein a height of the extended portion of the underfill covering a lower portion of the side surface of the first semiconductor chip ranges between about 10 μm to about 200 μm.

12. The semiconductor package of claim 1, wherein a surface roughness of the surface modification layer is less than a surface roughness of each of the opposing side surfaces of the first semiconductor chip and the second semiconductor chip.

13. A semiconductor package comprising:
a circuit board including an upper surface mounting a first semiconductor chip and mounting a second semiconductor chip adjacent to the first semiconductor chip, such that opposing side surfaces of the first semiconductor chip and second semiconductor chip are separated by an intermediate space;
a surface modification layer on the opposing side surfaces of the first semiconductor chip and the second semiconductor chip;
an underfill disposed between the first semiconductor chip and the second semiconductor chips and the circuit board, wherein the underfill includes an extended portion protruding into the intermediate space and having a height 40% or less of a mounting height of the first semiconductor chip; and
a molding member surrounding the first semiconductor chip and the second semiconductor chip, wherein an upper surface of the first semiconductor chip and an upper surface of the second semiconductor chip are coplanar with an upper surface of the molding member.

14. The semiconductor package of claim 13, wherein the surface modification layer comprises a polymer coating layer, and
wettability of the underfill with respect to a surface of the surface modification layer is less than wettability of the underfill with respect to the opposing side surfaces of the first semiconductor chip and the second semiconductor chip.

15. The semiconductor package of claim 14, wherein the surface modification layer comprises at least one of polyimide, benzocyclobutene, fluoroalkylsilane, polytetrafluoroethylene (PTFE), an alkyl ketene dimer, and polyalkylpyrrole.

16. The semiconductor package of claim 13, wherein a height of the extended portion of the underfill covering a lower portion of the side surface of the first semiconductor chip ranges between about 10 μm to about 200 μm.

17. The semiconductor package of claim 13, further comprising:
a heat sink disposed on the upper surface of the first semiconductor chip, the upper surface of the second semiconductor chip, and the upper surface of the molding member.

18. The semiconductor package of claim 13, wherein the first semiconductor chip comprises a logic chip, and the second semiconductor chip comprises a memory chip.

19. A semiconductor package comprising:
a circuit board including an upper surface mounting a semiconductor chip and mounting a dummy chip adjacent to the semiconductor chip, such that opposing side surfaces of the semiconductor chip and dummy chip are separated by an intermediate space;
an underfill disposed between the semiconductor chip and the circuit board and including an extended portion protruding into the intermediate space;
a surface modification layer on the opposing side surfaces of the semiconductor chip and the dummy chip, wherein wettability of the underfill with respect the surface modification layer is less than wettability of the underfill with respect to the opposing side surfaces of the semiconductor chip and the dummy chip; and
a molding member surrounding the semiconductor chip and the dummy chip.

20. The semiconductor chip of claim 19, wherein an upper surface of the semiconductor chip contacting a heat sink is higher than an upper surface of the dummy chip.
